(19) United States
(12) Patent Application Publication
(10) Pub. No.: US 2007/0155079 A1
(43) Pub. Date: Jul. 5, 2007

(54) GATE STRUCTURE OF SEMICONDUCTOR DEVICE AND METHOD OF MANUFACTURING THE SAME

(76) Inventor: Dae Kyeun Kim, Gyeonggi-do (KR)

Correspondence Address: SHERR & NOURSE, PLLC, 620 HERNDON PARKWAY, SUITE 200, HERNDON, VA, 20170, US

(21) Appl. No.: 11/617,105

(22) Filed: Dec. 28, 2006

(30) Foreign Application Priority Data
Dec. 29, 2005 (KR) 10-2005-0134054

(51) Int. Cl. H01L 21/8234

(52) U.S. Cl. 438/197; 257/368; 257/346; 438/299

(57) ABSTRACT

A semiconductor gate structure may be manufactured by forming an oxide layer over a silicon substrate before forming a gate insulating layer. The oxide is etched to form an opening that exposes a channel region. After forming a gate insulating layer in the opening, a gate conductor layer is deposited and is etched to form a gate. The oxide layer is etched to leave protective oxide regions at both edges of the gate insulating layer. The oxide regions protect the gate insulating layer from plasma damage during a gate etching process. Also, since the length of the gate insulating layer is smaller than the gate due to the protective oxides, ion diffusion is prevented from causing overlap in low density source and drain regions under the gate insulating layer.

The present application claims priority under 35 U.S.C. 119 and 35 U.S.C. 365 to Korean Patent Application No. 10-2005-0134054 (filed on Dec. 29, 2005), which is hereby incorporated by reference in its entirety.

### BACKGROUND

In the manufacture semiconductor devices, during an etching process of forming a gate, it has not been possible to prevent plasma damage to the edge of a gate insulating layer. This can cause degradation in a gate insulating layer due to the hot carrier effect. The reliability of a semiconductor device is reduced overall. Also, junctions formed by low density ion implantation cannot prevent partial overlapping due to ion diffusion into under the gate insulating layer, which degrades a gate induced drain leakage (GIDL) characteristic and generates parasitic capacitance to degrade the performance of the semiconductor device.

Hereinafter, a related technology will be described with reference to the drawings. FIGS. 1A to 1C are sectional views illustrating the gate structure of a semiconductor device and a method of manufacturing the same.

First, after performing a device isolation process and a well formation process on a silicon substrate, a gate insulating layer 11 and a gate conductive layer 12 are deposited over a silicon substrate 10, and are patterned to form a gate structure, as illustrated in FIG. 1A. At this time, due to the etching process, the edge 11a of the gate insulating layer 11 is damaged by plasma, which degrades the reliability of a semiconductor device.

Then, as illustrated in FIG. 1B, a thin oxide layer 13 is deposited and an ion implantation process forms low density source and drain regions 14. The temporary oxide layer 13 protects the surface of the silicon substrate 10 during the low density ion implantation process. However, the deposition and removal processes of the temporary oxide layer 13 further damage the gate insulating layer 11 and reduce the reliability of the semiconductor device. Also, the source and drain junction regions 14 partially overlap under the gate insulating layer 11 due to ion diffusion, which is yet another factor degrading the performance of the semiconductor device.

After removing the temporary oxide layer 13, as illustrated in FIG. 1C, a spacer insulating layer is deposited, and an anisotropic etching process forms gate spacers 15. The gate spacers 15 include an oxide 15a and a nitride 15b. Then, a high density ion implantation process forms high density source and drain regions 16. Subsequent processes such as an interlayer insulating layer and a metal wiring line are then performed.

### SUMMARY

Embodiments relate to a method of manufacturing a semiconductor device. More specifically, embodiments relate to a gate structure in which protective oxide regions are formed at the edge of a gate insulating layer, and a method of manufacturing the gate structure.

Embodiments relate to a gate structure in which it is possible to protect the edge of a gate insulating layer vulnerable to plasma damage.

Embodiments relate to a gate structure in which it is possible to prevent low density source and drain regions from partially overlapping under the gate.

Embodiments relate to a gate structure of a semiconductor device comprising a gate insulating layer formed over a channel region of a silicon substrate, protective oxide regions formed at both edges of the gate insulating layer, and a gate formed over the gate insulating layer and the protective oxide regions.

The length of the gate insulating layer may be smaller than the length of the gate by about 100 Å to 1,000 Å. The protective oxide regions may be thicker than the gate insulation layer and thinner than the gate. The thickness of the protective oxide regions may be about 50 Å to 500 Å. Spacers may be formed over the side walls of the gate and the protective oxide regions.

A method of manufacturing a gate according to embodiments includes forming an oxide layer over a silicon substrate, etching the oxide layer to form an opening which exposes a channel region of the silicon substrate, forming a gate insulating layer in the opening over the exposed silicon substrate, depositing a gate conductor layer to a thickness at least enough to fill the opening, and etching the gate conductor layer to form a gate and etching the oxide layer to form protective oxide regions at both edges of the gate insulating layer.

The oxide layer may be initially formed using a CVD process or a thermal oxidation process. A mask used to etch the opening in the oxide layer may also be used to etch the gate conductor layer and the oxide layer. The opening in the oxide layer has a length smaller than a length of the etched gate by about 100 Å to 1,000 Å. A spacer insulating layer is deposited over the side walls of the gate and over the oxide regions, using an anisotropic etching process to form gate spacers.

### BRIEF DESCRIPTION OF DRAWINGS

FIGS. 1A to 1C are sectional views illustrating the gate structure of a related semiconductor device and a method of manufacturing the same.

FIGS. 2A to 2F are sectional views illustrating the gate structure of a semiconductor device according to embodiments and a method of manufacturing the same.

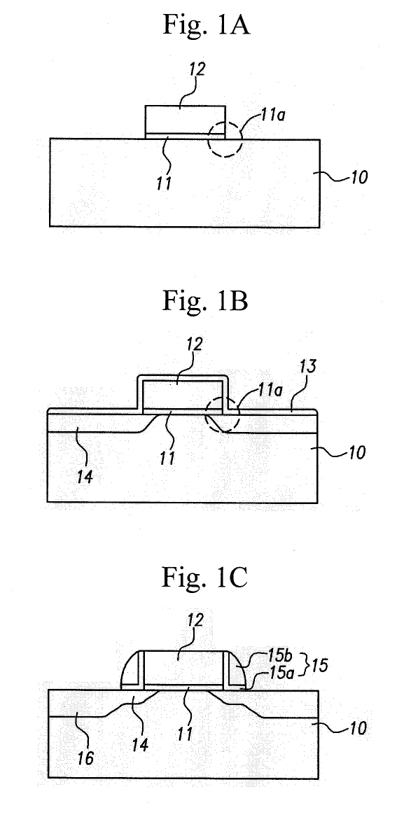

### DETAILED DESCRIPTION

Hereinafter, embodiments will be described in detail with reference to the attached drawings. In the drawings, some elements are exaggerated, omitted, or schematically illustrated; the sizes of the elements do not reflect the actual sizes of the elements.

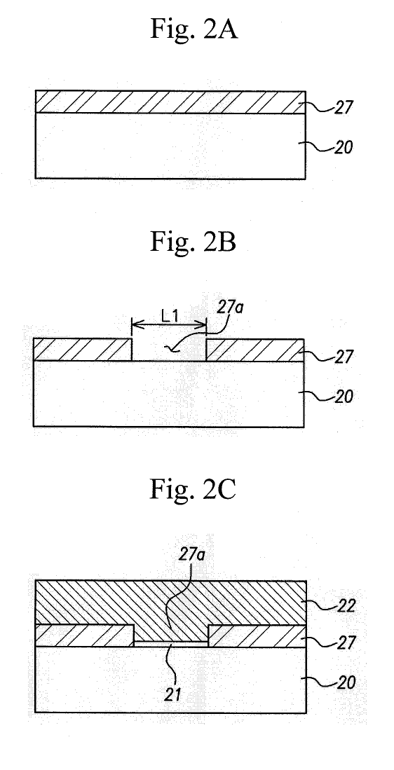

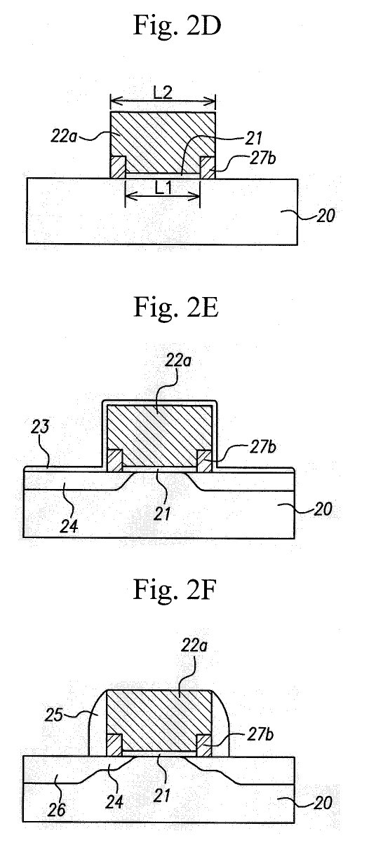

FIGS. 2A to 2F are sectional views illustrating the gate structure of a semiconductor device according to embodiments and a method of manufacturing the same.

First, as illustrated in FIG. 2A, an oxide layer 27 is deposited over a silicon substrate 20. A device isolation process and well formation process are performed over the silicon substrate 20. The oxide layer 27 can be formed by a chemical vapor deposition (CVD) process or a thermal oxidation process. The oxide layer 27 may be thicker than the gate insulating layer formed in subsequent steps (see e.g. FIGS. 2C and 2D). For example, the oxide layer may be about 50 Å to 500 Å thick. However, the thickness can vary in accordance with the characteristics of the semiconductor device.

Then, a photolithography process and an etching process are performed on the oxide layer 27. As a result, as illustrated in FIG. 2B, an opening 27a is formed in the oxide layer 27. The opening 27a exposes a gate channel region. The photolithography process of forming the opening 27a in the oxide layer 27 can be performed using a mask which may also be used as a gate mask. The length L1 of the opening 27a is smaller by about 100 Å to 1,000 Å than the length of the subsequently formed gate. This may be accomplished by controlling exposure dose and focus, although the same mask may be used. A difference in size between the opening 27a and the gate can vary in accordance with the desired characteristics of the semiconductor device.

Then, as illustrated in FIG. 2C, a gate insulating layer 21 is formed over the exposed silicon substrate 20 in the opening 27a. Therefore, the length of the gate insulating layer 21 is equal to the length of the opening 27a. A gate conductor layer 22 is deposited over the entire surface of the silicon substrate 20 with sufficient thickness to fill opening 27a. The gate conductor layer 22 and the oxide layer 27 are patterned by a photolithography process using the gate mask.

As a result, illustrated in FIG. 2D, a gate 22a is formed with oxide regions 27b left at the edges. The oxide regions 27b are for protecting the edges of the gate insulating layer 21. The protective oxide regions 27b may be less thick than the gate 22a and more thick than the gate insulating layer 21. In particular, the length L1 of the gate insulating layer 21 is smaller than the length L2 of the gate 22a due to the protective oxide regions 27b. As described above, the protective oxide regions 27b are formed at the both edges of the gate insulating layer 21. The protective oxide regions 27b prevent plasma damage to the gate insulating layer 21 during etching, and improve the reliability of the semiconductor device.

Then, as illustrated in FIG. 2E, a thin temporary oxide layer 23 is deposited in order to protect the silicon substrate 20. A low density ion implantation process forms low density source and drain regions 24. As described above, the length of the gate insulating layer 21 is smaller than the length of the gate 22a. Although ion diffusion occurs from the low density ion implantation, the extra separation provided by oxide regions 27b prevent the low density source and drain regions 24 from overlapping under the gate insulating layer 21. Also, oxide regions 27b prevent the gate insulating layer 21 from being damaged in the deposition and subsequent removal processes of the temporary oxide layer 23.

After removing the temporary oxide layer 23, a spacer insulating layer is deposited and an anisotropic etching process is performed. As a result, as illustrated in FIG. 2F, gate spacers 25 are formed over both side walls of gate 22a. A high density ion implantation process is performed using the gate spacers 25 as ion implantation masks to form high density source and drain regions 26.

Although not shown in the drawing, sequential processes may be performed to form an interlayer insulating layer and a metal interconnection layer or layers.

As described above, in the gate structure of the semiconductor device and method according to embodiments, the protective oxide regions are formed at the both edges of the gate insulating layer. The gate insulating layer is not exposed in the gate etching process, preventing plasma damage.

Therefore, the characteristics of the gate insulating layer are not degraded by the hot carrier effect and the reliability of the semiconductor device may be improved. Also, it is possible to prevent the gate insulating layer from being damaged in the deposition and removal processes of the temporary oxide layer used for low density ion implantation.

According to embodiments, it is possible to prevent the low density source and drain regions from being diffused and overlapping under the gate insulating layer. Therefore, it is possible to improve the gate induced drain leakage (GIDL) characteristics, to reduce parasitic capacitance, and to thus improve the performance of the semiconductor device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A gate structure of a semiconductor device, comprising:
a gate insulating layer formed over a channel region of a silicon substrate;
protective oxide regions formed at both edges of the gate insulating layer; and
a gate formed over the gate insulating layer and the protective oxide regions.

2. The gate structure of a semiconductor device of claim 1, wherein the length of the gate insulating layer is smaller than the length of the gate.

3. The gate structure of a semiconductor device of claim 1, wherein the length of the gate insulating layer is smaller than the length of the gate by about 100 Å to 1,000 Å.

4. The gate structure of a semiconductor device of claim 1, wherein the protective oxide regions are thicker than the gate insulation layer and thinner than the gate.

5. The gate structure of a semiconductor device of claim 1, wherein the thickness of the protective oxide regions is 50 Å to 500 Å.

6. The gate structure of a semiconductor device of claim 1, further comprising spacers formed over the side walls of the gate and the protective oxide regions.

7. A method of manufacturing a gate structure of a semiconductor substrate, the method comprising:
forming an oxide layer over a silicon substrate;
etching the oxide layer to form an opening which exposes a channel region of the silicon substrate;
forming a gate insulating layer in the opening over the exposed silicon substrate;
depositing a gate conductor layer to a thickness at least enough to fill the opening; and
etching the gate conductor layer to form a gate and etching the oxide layer to form protective oxide regions at both edges of the gate insulating layer.

8. The method of claim 7, wherein the oxide layer is initially formed using a CVD process.

9. The method of claim 7, wherein the oxide layer is initially formed using a thermal oxidation process.

10. The method of claim 7, wherein, a mask used to etch the opening in the oxide layer is also used to etch the gate conductor layer to form a gate and to etch the oxide layer to form protective oxide regions at both edges of the gate insulating layers.

11. The method of claim 7, wherein the opening in the oxide layer has a length smaller than a length of the etched gate.

12. The method of claim 7, wherein the opening in the oxide layer has a length smaller than a length of the etched gate by about 100 Å to 1,000 Å.

13. The method of claim 7, further comprising depositing a spacer insulating layer over the side walls of the gate and over the oxide regions.

14. The method of claim 13, wherein the spacer insulating layer is etched by an anisotropic etching process to form gate spacers.
